(19) United States
(12) Patent Application Publication
(10) Pub. No.: US 2007/0221959 A1
(43) Pub. Date: Sep. 27, 2007

(54) STRUCTURE AND METHOD FOR FABRICATING RECESSED CHANNEL MOSFET WITH FANNED OUT TAPERED SURFACE RAISED SOURCE/DRAIN

(75) Inventors: Huilong Zhu, Poughkeepsie, NY (US); Hong Lin, Poughkeepsie, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/308,410

(22) Filed: Mar. 22, 2006

(51) Int. Cl. H01L 29/76

(52) U.S. Cl. 257/213

(57) ABSTRACT

A raised source/drain field effect transistor has a surface of a raised source/drain that tapers downward in a direction of a gate electrode that is also included within the field effect transistor. The downward tapered surface is preferably an end surface. Due to the downward taper, the field effect transistor has a reduced gate to raised source/drain region capacitance. The downward taper also facilitates forming a halo region within the field effect transistor. Due to the raised source/drain, a silicide layer may be included within the raised source/drain region absent silicide penetration through a thin junction within an intrinsic source/drain region also included within the raised source/drain region.

### BACKGROUND OF THE INVENTION

1. Field of the Invention

The present invention relates generally to semiconductor structures and methods of fabricating the same. More particularly, the invention relates to enhanced performance field effect transistor (FET) structures and method of fabricating such FET structures.

2. Description of the Related Art

As field effect transistor structures are scaled to increasingly smaller dimensions, various performance effects become more pronounced. A performance effect that results from downward scaling of the gate electrode linewidth and corresponding channel width dimension in field effect transistors is known as a short channel effect (SCE). Short channel effects result from a generally inadequate control of a gate electrode over a channel region within a field effect transistor. Short channel effects are manifested as compromised electrical performance characteristics of a field effect transistor.

To address short channel effects, halo implant regions with profiles that encroach in a channel region of a field effect transistor are often used. The halo implant regions are usually formed using an angled ion implant method that uses a gate electrode as a mask. As an alternative or adjunct to limit short channel effects, limited junction depths are also typically used for extension and source/drain regions within field effect transistors. However, since source/drain regions within field effect transistors are generally subject to silicidation to provide low contact resistance connections thereto, limited junction depth source/drain regions may be difficult to reliably fabricate within field effect transistors.

To allow for reduced source/drain junction depths, while simultaneously providing sufficient silicon semiconductor substrate thickness for metal silicide layer formation, the use of raised source/drain layers upon intrinsic (i.e., semiconductor substrate based) source/drain regions has evolved. While raised source/drain layers provide adequate silicon semiconductor substrate thickness for low contact resistance silicide layer formation, they also contribute to parasitic gate to source/drain region capacitance that, in turn, also compromises field effect transistor performance. In addition, a generally conventional method for forming a raised source/drain layer is to selectively epitaxially grow the raised source/drain layer (i.e., typically but not exclusively of a silicon material) upon a heavily doped n-type or p-type silicon intrinsic source/drain region. However, it may be difficult to controllably epitaxially grow a silicon material upon such a heavily doped region, which may make it difficult to practice such a conventional method for forming a raised source/drain layer.

Thus, desirable within the semiconductor fabrication art are field effect transistor structures, and readily manufacturable methods for fabrication thereof, that simultaneously provide for reduced short channel effects and reduced gate to source/drain region parasitic capacitance effects.

### SUMMARY OF THE INVENTION

The invention provides a field effect transistor structure, and methods for fabricating the field effect transistor structure. The field effect transistor structure has a raised source/drain region with respect to a channel region (i.e., the channel is recessed with respect to the raised source/drain regions). The raised source/drain region has a surface (i.e., typically an end surface) downwardly tapered in the direction of a gate electrode. Thus, the raised source/drain region has a fan out shape with respect to the gate electrode. Due to the raised source/drain region, a silicide layer may be included within the raised source/drain region, while not compromising a limited source/drain region junction depth adjoining a channel region. Due to the downwardly tapered raised source/drain region surface in the direction of the gate electrode, the field effect transistor also has a reduced gate to source/drain region parasitic capacitance. Finally, the downwardly tapered raised source/drain region surface in the direction of the gate electrode facilitates forming a halo ion implantation region within the field effect transistor structure since an angle of the downwardly tapered surface (with respect to an orthogonal) may under certain circumstances be readily controlled to be equal to or larger than a tilt angle (with respect to the orthogonal) used when forming the halo ion implant region. The halo ion implant region may thus be formed of dimensions that provide enhanced short channel effect control.

A structure in accordance with the invention comprises a gate electrode located over a channel region within a semiconductor substrate. The channel region separates a pair of source/drain regions that is raised with respect to the channel region. Each of the source/drain regions has a surface that has a downward taper in the direction of the gate electrode.

The methods for fabricating the structure in accordance with the invention use a patterning of an epitaxial surface semiconductor layer that may be formed upon an epitaxial etch stop semiconductor layer which is, in turn, formed upon a semiconductor substrate. The patterning provides a channel region coplanar with a pair of intrinsic source/drain regions within the semiconductor substrate. A pair of patterned epitaxial etch stop semiconductor layers and a pair of patterned epitaxial surface semiconductor layers are used in forming a pair of raised source/drain regions.

A first method in accordance with the invention comprises patterning at least an epitaxial surface semiconductor layer located over a semiconductor substrate, to form at least a pair of patterned epitaxial surface semiconductor layers separated by a trench that exposes the semiconductor substrate. This particular method also includes forming a gate dielectric upon the semiconductor substrate at the bottom of the trench. The first method also includes forming a gate electrode upon the gate dielectric. Finally, the first method includes forming a pair of source/drain regions into at least the semiconductor substrate while using at least the gate electrode as a mask.

A second method in accordance with the invention incorporates a crystallographically specific etch when patterning the epitaxial surface semiconductor layer to form a pair of patterned epitaxial surface semiconductor layers.

Thus, the second method comprises crystallographically specifically etching an epitaxial surface semiconductor layer located upon an epitaxial etch stop semiconductor layer further located upon a semiconductor substrate, to form a pair of patterned epitaxial surface semiconductor layers separated by an outward tapered trench that exposes the epitaxial etch stop semiconductor layer. The second method also includes etching the epitaxial etch stop semiconductor layer exposed within the outward tapered trench to form a pair of patterned epitaxial etch stop semiconductor layers that exposes the semiconductor substrate. The second method also includes forming a gate dielectric upon the semiconductor substrate at the bottom of the outward tapered trench. The second method also includes forming a gate electrode upon the gate dielectric. Finally, the second method of the present invention also includes forming a pair of source/drain regions into at least the semiconductor substrate while using at least the gate electrode as a mask.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, that form a material part of this disclosure, wherein:

FIG. 1 to FIG. 13 show a series of schematic cross-sectional and plan-view diagrams illustrating the results of progressive stages in fabricating a field effect transistor structure in accordance with an embodiment of the invention.

FIG. 14 shows a schematic cross-sectional diagram of a field effect transistor structure fabricated in accordance with an additional embodiment of the invention.

### DESCRIPTION OF THE PREFERRED EMBODIMENTS

The present invention, which provides a semiconductor structure comprising a field effect transistor with enhanced performance, and methods of fabricating the same, will now be described in greater detail by referring to the following disclosure and drawings that accompany the present application. The drawings of the present application are provided for illustrative proposes and, as such, the drawings are not drawn to scale.

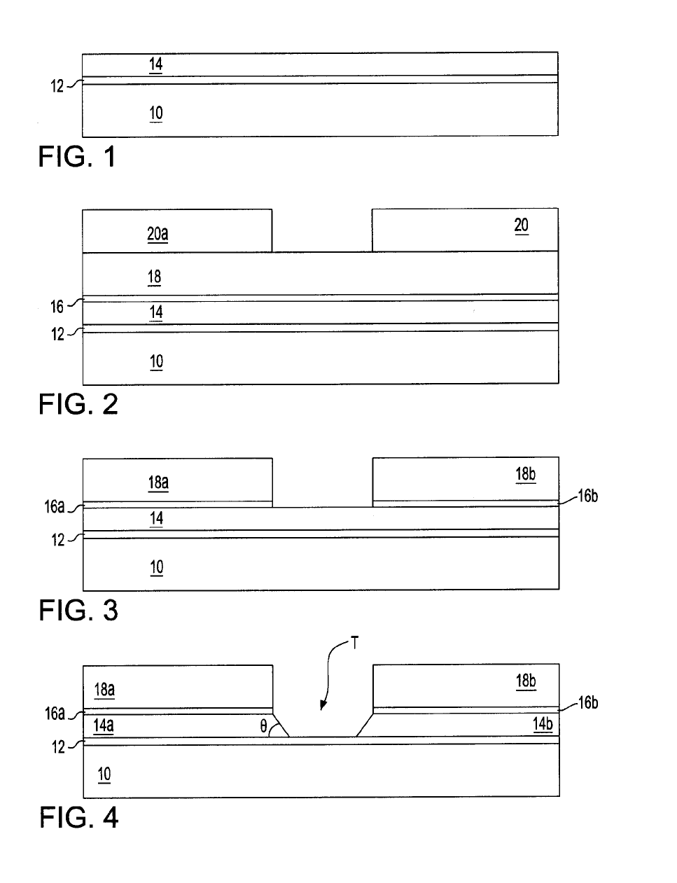

FIGS. 1-13 are directed towards an embodiment of the present invention. The embodiment is designated as the first embodiment of the invention.

FIG. 1 shows an initial structure that is used in the present invention, which includes a semiconductor substrate 10. An epitaxial etch stop semiconductor layer 12 is located upon the semiconductor substrate 10. Finally, an epitaxial surface semiconductor layer 14 is located upon the epitaxial etch stop semiconductor layer 12.

The semiconductor substrate 10 may comprise any of several semiconductor materials that are known in the art. Non-limiting examples of semiconductor materials include silicon, germanium, silicon-germanium alloy, silicon carbide alloy, silicon-germanium carbide alloy and compound semiconductor materials. Non-limiting examples of compound semiconductor materials include gallium arsenide, indium arsenide and indium phosphide semiconductor materials. Typically, the semiconductor substrate 10 comprises a silicon or silicon-germanium alloy semiconductor material having a thickness from about 1 to about 3 mils.

While the instant embodiment illustrates the invention within the context of the semiconductor substrate 10 that comprises a bulk semiconductor substrate, the invention is not intended to be so limited. Rather, the invention may also be practiced using a semiconductor substrate 10 that comprises a semiconductor-on-insulator substrate (as will be illustrated in further detail below). A semiconductor-on-insulator substrate comprises a laminated structure including a base semiconductor substrate, a buried dielectric layer located thereupon and a surface semiconductor layer located further thereupon. The invention also contemplates the use of a hybrid orientation (HOT) substrate. A hybrid orientation substrate comprises a plurality of semiconductor regions having a plurality of crystallographic orientations, all fabricated within a single semiconductor substrate.

The epitaxial etch stop semiconductor layer 12 is intended to be epitaxially grown to preserve the crystallographic orientation of the semiconductor substrate 10. However, the epitaxial etch stop semiconductor layer 12 comprises a different semiconductor material than the epitaxial surface semiconductor layer 14 located thereupon. When the epitaxial surface semiconductor layer 14 comprises (as a preferred example) a silicon semiconductor material, the epitaxial etch stop semiconductor layer 12 may advantageously comprise a silicon-germanium alloy (i.e., from about 20 to about 30 atomic percent germanium) semiconductor material. Typically, the epitaxial etch stop semiconductor layer 12 has a thickness from about 50 to about 100 Angstroms.

The epitaxial surface semiconductor layer 14, which is shown in FIG. 1 disposed on layer 12, also comprises an epitaxial semiconductor material whose composition may be etched selectively with respect to the epitaxial etch stop semiconductor layer 12. Typically, the semiconductor substrate 10 and the epitaxial surface semiconductor layer 14 comprise an identical semiconductor material having an identical crystallographic orientation, although they need not necessarily have an identical dopant concentration. Typically, the epitaxial surface semiconductor layer 14 has a thickness from about 200 to about 500 Angstroms. Although the invention is not so limited, and as noted above, each of the semiconductor substrate 10 and the epitaxial surface semiconductor layer 14 preferably comprises a silicon semiconductor material, while the epitaxial etch stop semiconductor layer 12 preferably comprises a silicon-germanium alloy semiconductor material.

FIG. 2 shows a pad dielectric layer 16 located upon the epitaxial surface semiconductor layer 14. FIG. 2 also shows a hard mask layer 18 located upon the pad dielectric layer 16. Finally, FIG. 2 also shows a pair (in cross sectional view only) of patterned photoresist layers 20a and 20b located upon the hard mask layer 18.

The pad dielectric layer 16 may comprise any of several dielectric materials. Oxides and oxynitrides of silicon are common and non-limiting examples of pad dielectric materials. Oxides and oxynitrides of other elements are not excluded. The pad dielectric layer 16 may be formed using methods including but not limited to: thermal or plasma oxidation or nitridation methods, chemical vapor deposition methods and physical vapor deposition methods. Typically, the pad dielectric layer 16 comprises an oxide of the semiconductor material which comprises the epitaxial surface semiconductor layer 14. More typically, the pad dielectric layer 16 comprises a thermal silicon oxide material having a thickness from about 50 to about 100 Angstroms.

The hard mask layer 18 may similarly comprise any of several hard mask materials that are conventional in the semiconductor fabrication art. Non-limiting examples include nitrides and oxynitrides of silicon. But again, nitrides and oxynitrides of other elements are not excluded. The hard mask layer 18 may generally be formed using any of the several methods that may be used for forming the pad dielectric layer 16. Deposition methods are preferred since thicker layers may be more readily formed. From a practical perspective, silicon nitride hard mask materials may be readily formed, and are also appropriate with the use of silicon oxide materials for forming the pad dielectric layer 16. Typically, the hard mask layer 18 comprises a silicon nitride hard mask material having a thickness from about 200 to about 400 Angstroms.

The pair of patterned photoresist layers 20a and 20b may comprise any of several photoresist materials. Non-limiting examples include positive photoresist materials, negative photoresist materials and hybrid photoresist materials. Typically, each of the pair of patterned photoresist layers 20a and 20b has a thickness from about 2000 to about 5000 Angstroms. Each of the pair of patterned photoresist layers 20a and 20b is typically formed using conventional spin-coating and photoimaging methods and materials. The invention is not, however, so limited.

FIG. 3 shows the results of sequentially etching the hard mask layer 18 and the pad dielectric layer 16 to form a corresponding pair of patterned hard mask layers 18a and 18b and patterned pad dielectric layers 16a and 16b, while using the pair of patterned photoresist layers 20a and 20b as an etch mask. The hard mask layer 18 and the pad dielectric layer 16 may be patterned using etch methods that are conventional in the semiconductor fabrication art. Plasma etch methods or other anisotropic etch methods are more common and desirable insofar as they provide generally straight sidewalls to the pair of patterned hard mask layers 18a and 18b and the pair of patterned pad dielectric layers 16a and 16b. Typically, each of the hard mask layer 18 and the pad dielectric layer 16 is sequentially etched and patterned while using a plasma etch method that uses a fluorine containing etchant gas composition. Other methods and materials may alternatively be used.

FIG. 4 shows the results of crystallographically specifically etching the epitaxial surface semiconductor layer 14 to provide a pair of patterned epitaxial surface semiconductor layers 14a and 14b. The epitaxial surface semiconductor layer 14 may be crystallographically specifically etched to form the pair of patterned epitaxial surface semiconductor layers 14a and 14b, while using a wet chemical crystallographically specific directional etch or a dry plasma crystallographically specific directional etch. For example, when the epitaxial surface semiconductor layer 14 comprises a silicon semiconductor material having a 111 surface crystallographic orientation, a desirable crystallographically specific directional etch may comprise an aqueous tetramethylammonium hydroxide (TMAH) solution (e.g., from about 2 to about 10 weight percent TMAH). Such an aqueous TMAH solution has an etch selectivity for a 111 silicon material to a 111 silicon-germanium alloy material (e.g., at about 20 atomic percent germanium) of about 20:1. The crystallographically specific etch yields an endwall angle θ of 54.7° for each of the pair of patterned epitaxial surface semiconductor layers 14a and 14b with respect to the plane of the epitaxial etch stop semiconductor layer 12. Other crystallographically specific directional etches (such as (110) plane), whether wet chemical or dry plasma, may also be used within the instant embodiment.

As is illustrated in FIG. 4 the crystallographically specific directional etching of the epitaxial surface semiconductor layer 14 to provide the pair of patterned epitaxial surface semiconductor layers 14a and 14b yields the pair of patterned epitaxial surface semiconductor layers 14a and 14b with a pair of endwalls that taper downward in the direction of a trench T that separates that pair of patterned epitaxial surface semiconductor layers 14a and 14b. The invention is not, however, limited to only endwalls of a pair of patterned epitaxial surface semiconductor layers 14a and 14b that taper downwardly towards the trench T, but rather may also include top surfaces of a pair of patterned epitaxial surface semiconductor layers (such as the pair of patterned epitaxial surface semiconductor layers 14a and 14b) that downwardly taper towards a trench (such as the trench T).

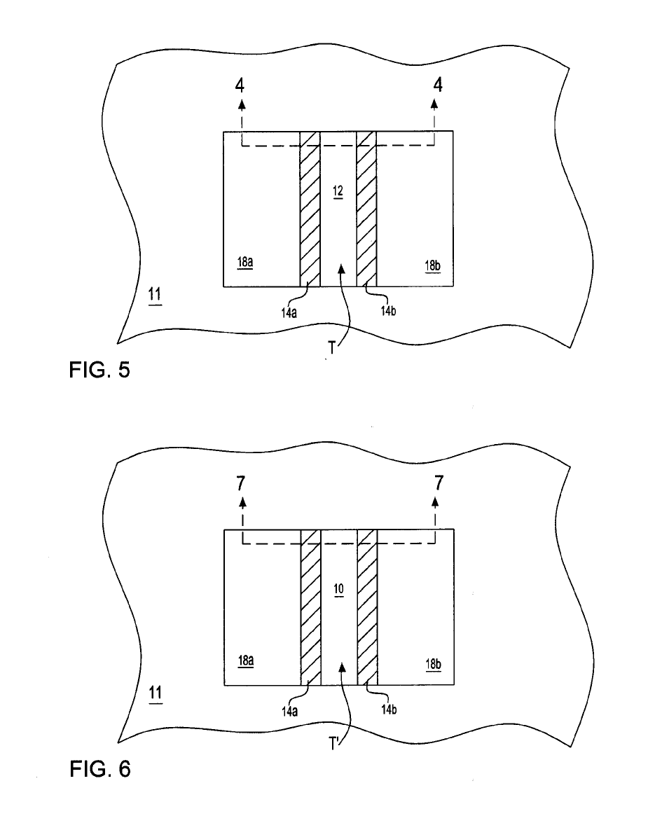

FIG. 5 shows a schematic plan-view diagram corresponding with the schematic cross-sectional diagram of FIG. 4. Specifically, FIG. 5 shows the pair of patterned hard mask layers 18a and 18b. Tapered portions of the pair of patterned epitaxial surface semiconductor layers 14a and 14b are shown exposed beneath the pair of patterned hard mask layers 18a and 18b. The pair of patterned epitaxial surface semiconductor layers 14a and 14b is separated by the trench T. Exposed at the bottom of the trench T is a portion of the epitaxial etch stop semiconductor layer 12. Finally, FIG. 5 illustrates an isolation region 11 that surrounds an active region mesa that comprises the epitaxial etch stop semiconductor layer 12, the pair of patterned epitaxial surface semiconductor layers 14a and 14b, the pair of patterned pad dielectric layers 16a and 16b and the pair of patterned hard mask layer 18a and 18b that are sequentially layered upon or over the semiconductor substrate 10.

FIG. 6 shows a schematic plan-view diagram illustrating the results of further processing of the semiconductor structure whose schematic plan-view diagram is illustrated in FIG. 5. Specifically, FIG. 6 shows a portion of the semiconductor substrate 10 exposed interposed between the tapered portions of the pair of patterned epitaxial surface semiconductor layers 14a and 14b, rather than the portion of the epitaxial etch stop semiconductor layer 12 that is illustrated in FIG. 5. FIG. 6 thus implicitly also shows the results of etching the epitaxial etch stop semiconductor layer 12 to form a pair of patterned epitaxial etch stop semiconductor layers 12a and 12b, and to thus form an extended trench T′ from the trench T that is illustrated in FIG. 4 and FIG. 5. The semiconductor structure that is illustrated in FIG. 6 results from etching and removal of a portion of the epitaxial etch stop semiconductor layer 12 at the base of the trench T that is illustrated in FIG. 5.

FIG. 7 shows a schematic cross-sectional diagram that corresponds with the schematic plan-view diagram of FIG. 6. FIG. 7 again shows the results of selectively etching the portion of the epitaxial etch stop semiconductor layer 12 exposed at the bottom of the trench T that is illustrated in FIG. 4 or FIG. 5, to form a pair of patterned epitaxial etch stop semiconductor layers 12a and 12b that expose a portion of the semiconductor substrate 10. The extended trench T′ is formed from the trench T. When patterning the epitaxial etch stop semiconductor layer 12 to form the pair of patterned epitaxial etch stop semiconductor layers 12a and 12b, the semiconductor substrate 10 serves as an etch stop layer.

The epitaxial etch stop semiconductor layer 12 may be patterned to form the pair of patterned epitaxial etch stop semiconductor layers 12a and 12b while using any of several etch methods and materials. Non-limiting examples include wet chemical etch methods and materials, dry plasma etch methods and materials, and aggregate methods and materials thereof. While any of the foregoing methods and materials may be used, certain plasma etch methods that utilize fluorine containing etchant gas compositions provide a desired selectivity for a silicon-germanium alloy semiconductor material (that preferably comprises the epitaxial etch stop semiconductor layer 12) in comparison with a silicon semiconductor material (that preferably comprises the semiconductor substrate 10). Particular examples of fluorine containing etchant gases within such fluorine containing etchant gas compositions include carbon tetrafluoride (i.e., CF4) and trifluoromethane (i.e., CHF3).

FIG. 8 shows a pair of first spacer layers 20a and 20b located covering the pair of sidewalls defined by the pair of patterned epitaxial etch stop semiconductor layers 12a and 12b, the pair of patterned epitaxial surface semiconductor layers 14a and 14b, the pair of patterned pad dielectric layers 16a and 16b and the pair of patterned hard mask layers 18a and 18b. The pair of first spacer layers 20a and 20b provides a narrowed trench T″ from the extended trench T′.

The pair of first spacer layers 20a and 20b may comprise any of several spacer materials that are conventional in the semiconductor fabrication art. Oxides, nitrides and oxynitrides of silicon are again common spacer materials. Silicon oxides are particularly common spacer materials. Typically the pair of spacer layers 20a and 20b is formed using a silicon oxide blanket layer deposition and anisotropic etch back method that is otherwise generally conventional in the semiconductor fabrication art.

FIG. 9 first shows a gate dielectric 22 located upon an exposed portion of the semiconductor substrate 10 within the narrowed trench T″ that is illustrated in FIG. 8. FIG. 9 also shows a gate electrode 24 located upon the gate dielectric 22.

The gate dielectric 24 may comprise generally conventional dielectric materials having a dielectric constant from about 4 to about 20, measured in vacuum. Such generally conventional dielectric materials may include, but are not limited to oxides, nitrides and oxynitrides of silicon. In addition, the gate dielectric 22 may also comprise generally higher dielectric constant dielectric materials having a dielectric constant from about 20 up to at least about 100. Non-limiting examples of such general higher dielectric constant dielectric materials include hafnium oxides, hafnium silicates, aluminum oxides, titanium oxides, zirconium oxides, lanthanum oxides, strontium titanates, lanthanum-aluminum oxides, barium-strontium-titanates (BSTs), lead-zirconate-titantates (PZTs) and mixtures thereof. Any of the foregoing dielectric materials may be formed using methods that are conventional in the semiconductor fabrication art. Non-limiting examples of methods include thermal or plasma oxidation or nitridation methods, chemical vapor deposition methods and physical vapor deposition methods. As is implied by the location and sizing of the gate dielectric 22 that is illustrated in FIG. 9, the gate dielectric 22 typically comprises a thermal silicon oxide dielectric material having a thickness from about 20 to about 70 Angstroms.

The gate electrode 24 may comprise any of several gate electrode materials. The gate electrode materials may comprise any of several metals, metal alloys, metal nitrides and metal suicides as non-limiting examples of gate electrode materials. Alternatively, the gate electrode 24 may also comprise a doped polysilicon material (i.e., having about 1e18 to about 1e22 dopant atoms per cubic centimeter), a doped SiGe material or a polycide material (i.e., a doped polysilicon/metal suicide stack) material. The gate electrode materials may be deposited using any of several methods. Non-limiting examples include chemical vapor deposition methods (including in particular atomic layer chemical vapor deposition methods) and physical vapor deposition methods. Typically, the gate electrode 24 comprises a doped polysilicon material that has a thickness from about 1000 to about 2500 Angstroms.

The gate electrode 24 that is illustrated in FIG. 9 typically results from a blanket polysilicon layer deposition and anisotropic etchback, to form the gate electrode 24 of a rectangular shape between the pair of spacer layers 20a and 20b.

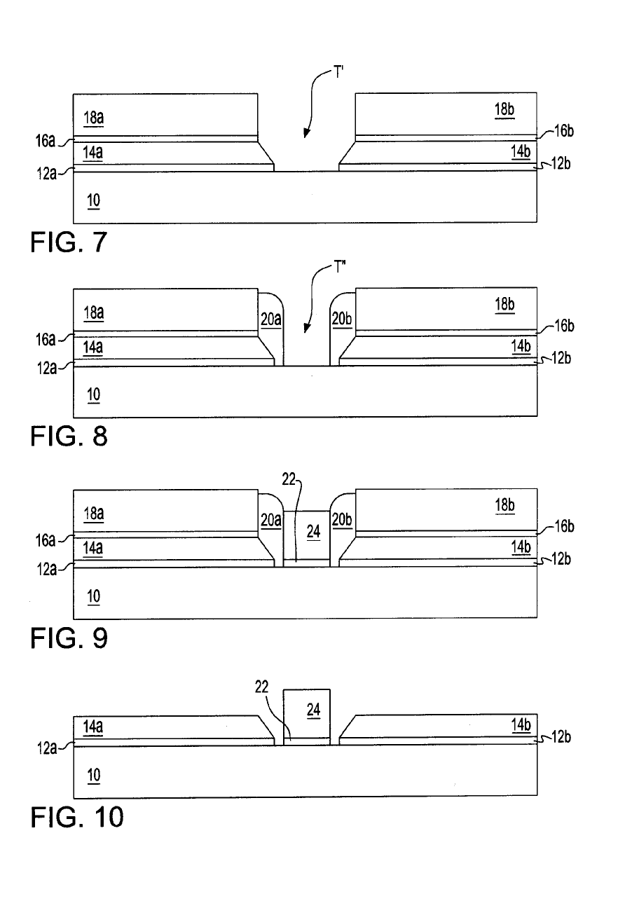

FIG. 10 shows the results of stripping the pair of patterned hard mask layers 18a and 18b, the pair of patterned pad dielectric layers 16a and 16b and the pair of first spacer layers 20a and 20b from the semiconductor structure whose schematic cross-sectional diagram is illustrated in FIG. 9. As a result of stripping the pair of patterned hard mask layers 18a and 18b, the pair of patterned pad dielectric layers 16a and 16b and the pair of first spacer layers 20a and 20b, the gate electrode 24 that is aligned upon the gate dielectric layer 22 remains located over the semiconductor substrate 10. The gate electrode 24 is spaced from the downward tapered (i.e., fanned out) ends of the pair of patterned epitaxial surface semiconductor layers 14a and 14b.

The pair of patterned hard mask layers 18a and 18b, the pair of patterned pad dielectric layers 16a and 16b and the pair of first spacer layers 20a and 20b may be stripped using methods and materials that are conventional in the semiconductor fabrication art. The methods and materials may include, but are not limited to: wet chemical stripping methods and materials, dry plasma stripping methods and materials and aggregate stripping methods and materials thereof. When the pair of patterned hard mask layers 18a and 18b comprises a silicon nitride material, the pair of patterned hard mask layers 18a and 18b may often efficiently be stripped selectively with respect to the pair of patterned pad dielectric layers 16a and 16b (when formed of a silicon oxide material) and the pair of first spacer layers 20a and 20b (when formed of a silicon oxide material) while using an aqueous phosphoric acid etchant at elevated temperature (e.g., from about 80 to about 100 degrees centigrade). In addition, the pair of patterned pad dielectric layers 16a and 16b and the pair of first spacer layers 20a and 20b (when each is formed of a silicon oxide material) might additionally preferably be stripped using a plasma etch method that avoids undercutting damage to the gate dielectric layer 22. Alternatively, a wet chemical etch method using an aqueous hydrofluoric acid etchant may be used for etching and stripping the pair of patterned pad dielectric layers 16a and 16b and the pair of first spacer layers 20a and 20b.

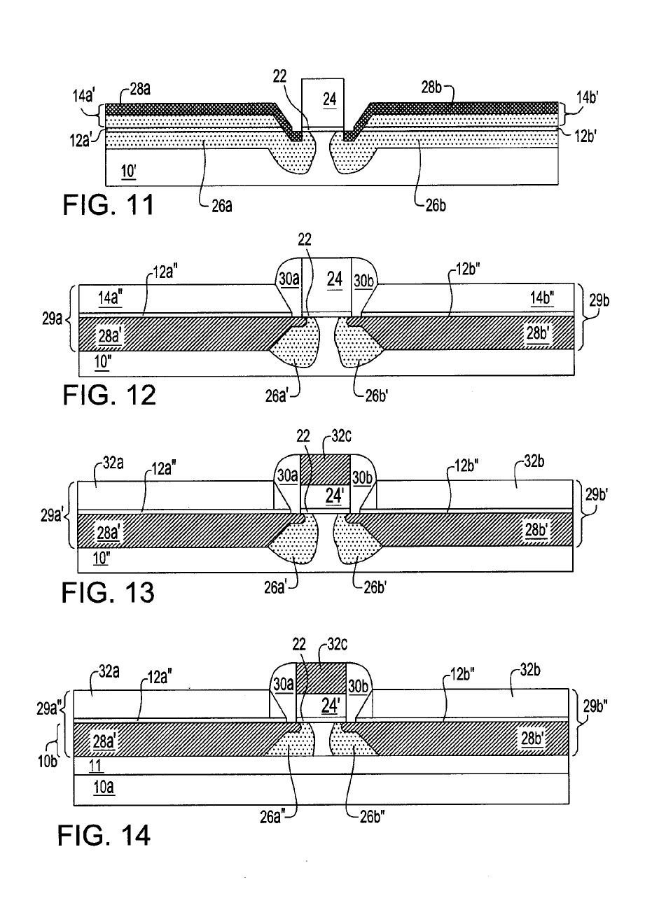

FIG. 11 shows a pair of extension regions 28a and 28b located transecting through: (1) a pair of twice implanted patterned surface semiconductor layers 14a′ and 14b′; and (2) a pair of twice implanted patterned epitaxial etch stop semiconductor layers 12a′ and 12b′; and (3) terminating within a twice implanted semiconductor substrate 10. FIG. 11 finally shows a pair of halo regions 26a and 26b into which is nested the pair of extension regions 28a and 28b.

As is understood by a person skilled in the art, due to the downward taper of the endwalls of the pair of twice implanted patterned surface semiconductor layers 14a′ and 14b′ in the direction of the gate electrode 24 (i.e., in comparison with a non-tapered vertical endwall or an otherwise reentrant sidewall), the halo regions 26a and 26b are more easily and readily formed of desirable dimensions. Within FIG. 11, either the pair of extension regions 28a and 28b or the pair of halo regions 26a and 26b may be formed first. The pair of halo regions 26a and 26b is of the same polarity as the channel region beneath the gate electrode 24, but comprising a higher dopant concentration from about 1.0×10¹⁷ to about 1.0×10¹⁹ dopant atoms per cubic centimeter. The pair of extension regions 28a and 28b has a polarity opposite the polarity of the channel region beneath the gate electrode 24. Typically, each of the pair of extension regions 28a and 28b has a dopant concentration from about 1.0×10¹⁹ to about 1.0×10²¹ dopant atoms per cubic centimeter. The pair of extension regions 28a and 28b is typically formed while using an orthogonal ion implant method that uses the gate electrode 24 as a mask. The pair of halo regions 26a and 26b also typically uses the gate electrode 24 as a mask, but with a large angle tilt implant (LATI) method rather than an orthogonal implant method. Within the invention, the endwall taper angle of the pair of twice implanted patterned surface semiconductor layers 14a′ and 14b′ is readily greater than a tilt angle used within the large angle tilt implant method, thus facilitation proper formation of the pair of halo regions 26a and 26b.

FIG. 12 first shows a pair of second spacer layers 30a and 30b located interposed between the pair of twice implanted patterned epitaxial surface semiconductor layers 14a′ and 14b′ and the gate electrode 24 that are illustrated in FIG. 11. The pair of spacer layers 30a and 30b may comprise materials, have dimensions and be formed using methods analogous, equivalent or identical to the materials, dimensions and methods used for forming the pair of first spacer layers 20a and 20b that is illustrated in FIG. 8 and FIG. 9. Typically, the pair of second spacer layers 30a and 30b also comprises a silicon oxide dielectric material. Similarly with the pair of first spacer layers 20a and 20b, the pair of second spacer layers 30a and 30b is typically also formed using a blanket layer deposition and anisotropic etchback method.

FIG. 12 also shows a pair of intrinsic source/drain regions 28a′ and 28b′ that incorporates the pair of extension regions 28a and 28b that is illustrated in FIG. 11. The pair of intrinsic source/drain regions 28a′ and 28b′ is coplanar with a channel region beneath the gate electrode 24 within a three times implanted semiconductor substrate 10″. The pair of intrinsic source/drain regions 28a′ and 28b′ is thus also located within the three times implanted semiconductor substrate 10″. Located upon the pair of intrinsic source/drain regions 28a′ and 28b′ is a pair of three times implanted epitaxial etch stop semiconductor layers 12a″ and 12b″. Further located upon the pair of three times implanted epitaxial etch stop semiconductor layers 12a″ and 12b″ is a pair of three times implanted epitaxial surface semiconductor layers 14a″ and 14b″. The pair of laminates comprising: (1) the pair of intrinsic source/drain regions 28a′ and 28b′; (2) the pair of three times implanted epitaxial etch stop semiconductor layers 12a″ and 12b″; and (3) the pair of three times implanted epitaxial surface semiconductor layers 14a″ and 14b″, comprises a pair of raised source/drain regions 29a and 29b within the context of the first embodiment. Other laminated constructions are not excluded for source/drain regions within other embodiments. Also illustrated within FIG. 12 is a pair of truncated halo regions 26a′ and 26b′ that result from overdoping of the pair of halo regions 26a and 26b that is illustrated within FIG. 11 within the pair of implanted epitaxial surface semiconductor layers 14a″ and 14b″, the pair of implanted epitaxial etch stop semiconductor layers 12a″ and 12b″ and the intrinsic source/drain regions 28a′ and 28b′ that are illustrated in FIG. 12.

FIG. 12 shows a schematic cross-sectional diagram of a semiconductor structure comprising a field effect transistor in accordance with a first embodiment of the invention. The field effect transistor comprises a pair of implanted epitaxial surface semiconductor layers 14a″ and 14b″ each of which has a surface (i.e., an end surface) that tapers downward in the direction of a gate electrode 24. The pair of implanted epitaxial surface semiconductor layers 14a″ and 14b″ comprises a pair of upper lying layers within a pair of raised source/drain regions 29a and 29b. Due to a downward taper of the implanted epitaxial surface semiconductor layers 14a″ and 14b″, the pair of implanted epitaxial surface semiconductor layers 14a″ and 14b″ may have an enhanced separation distance from the gate electrode 24. Due to that enhanced separation distance, a parasitic capacitance between each of the implanted epitaxial surface semiconductor layers 14a″ or 14b″ (and the pair of raised source/drain regions 29a and 29b) and the gate electrode 24 is reduced.

FIG. 13 shows a series of suicide layers 32a, 32b and 32c. The pair of suicide layers 32a and 32b result from a complete silicidation of the pair of three times implanted epitaxial surface semiconductor layers 14a″ and 14b″. The silicide layer 32c results from partial silicidation of the gate electrode 24 to yield a depleted gate electrode 24′. The depleted gate electrode 24′ and the silicide layer 32c comprise a polycide gate electrode.

Due to the possibility of differential rates of silicidation between the semiconductor materials that comprise the pair of implanted epitaxial surface semiconductor layers 14a″ and 14b″, and the pair of implanted epitaxial etch stop semiconductor layers 12a″ and 12b″, the pair of implanted epitaxial etch stop semiconductor layers 12a″ and 12b″ may under certain circumstances serve as a pair of silicidation stop layers. A non limiting example of such a circumstance exists when forming a cobalt silicide, for which a silicon-germanium alloy material (i.e., comprising the pair of implanted epitaxial etch stop semiconductor layers 12a″ and 12b″) may serve as a silicidation stop layer. Alternatively, a blanket metal silicide forming metal layer used as a metal source material for forming the series of silicide layers 32a, 32b and 32c may be deposited with an appropriate thickness to completely silicide the pair of implanted epitaxial surface semiconductor layers 14a″ and 14b″ when forming the pair of silicide layers 32a and 32b, but incompletely silicide the gate electrode 24 when forming the silicide layer 32c.

The metal silicide layers 32a, 32b and 32c may comprise any of several metal silicide forming metals. Non-limiting examples include titanium, tungsten, vanadium, cobalt and platinum metals. The metal silicide layers 32a, 32b and 32c need not necessarily comprise the same metal silicide material, but the metal silicide layers 32a, 32b and 32c will typically comprise the same metal silicide material.

FIG. 13 shows an additional semiconductor structure further in accordance with the first embodiment. FIG. 13 shows a semiconductor structure analogous to the semiconductor structure of FIG. 12, but with: (1) partial silicidation of the gate electrode 24 that is illustrated in FIG. 12 to provide a polycide gate electrode that comprises a depleted gate electrode 24′ and a silicide layer 32c located thereupon; and (2) substitution of the pair of silicide layers 32a and 32b for the pair of implanted epitaxial surface semiconductor layers 14a″ and 14b″.

Within FIG. 13, a pair of raised source drain regions 29a′ and 29b′ comprises a pair of laminated structures comprising: (1) a pair of intrinsic source/drain regions 28a′ and 28b′ located within a three times implanted semiconductor substrate 10″; (2) a pair of implanted epitaxial etch stop semiconductor layers 12a″ and 12b″ located upon the pair of intrinsic source/drain regions 28a′ and 28b′; and (3) a pair of silicide layers 32a and 32b located upon the pair of implanted epitaxial etch stop semiconductor layers 12a″ and 12b″.

Within this further embodiment of the first embodiment, the pair of raised source/drain regions 29a′ and 29b′ (that is raised with respect to the recessed channel region within the three times implanted semiconductor substrate 10″) comprise the pair of silicide layers 32a and 32b that have the end surfaces that taper in the direction of the polycide gate electrode that comprises the silicide layer 32c and the depleted gate electrode 24′. Within this further embodiment, the downward taper of the pair of silicide layers 32a and 32b also provides for a reduced gate electrode to raised source/drain region 29a′ or 29b′ parasitic capacitance. In addition, since the raised source/drain regions 29a′ and 29b′ are raised with respect to the channel beneath the gate electrode 24′, the pair of silicide layers 32a and 32b may be formed with an adequate and considerable thickness of up to about 300 to about 500 Angstroms, while still providing an adequate junction depth of from about 100 to about 500 Angstroms within the pair of intrinsic source/drain regions 28a′ and 28b′.

FIG. 14 shows a semiconductor structure in accordance with an additional embodiment of the invention. The additional embodiment of the invention comprises a second embodiment of the invention.

FIG. 14 shows a semiconductor structure largely analogous with the semiconductor structure of FIG. 13, but wherein the semiconductor structure uses a semiconductor-on-insulator substrate rather than a bulk semiconductor substrate 10 that is used within the first embodiment. The semiconductor-on-insulator substrate comprises a base semiconductor substrate 10a, a buried dielectric layer 11 located thereupon and an intrinsic surface semiconductor layer 10b further located thereupon.

Within the semiconductor-on-insulator substrate, each of the base semiconductor substrate 10a and the intrinsic surface semiconductor layer 10b may comprise any of the several semiconductor materials from which the semiconductor substrate 10 may be comprised within the first embodiment. The base semiconductor substrate 10a and the intrinsic surface semiconductor layer 10b may comprise the same semiconductor material or a different semiconductor material with respect to any of semiconductor composition, dopant concentration/conductivity type, and crystallographic orientation.

The buried dielectric layer 11 may comprise any of several dielectric materials. Non-limiting examples include oxides, nitride and oxynitrides, typically of silicon. However, oxides, nitrides and oxynitrides of other elements are not excluded. Typically, the buried dielectric layer 11 has a thickness from about 200 to about 500 Angstroms.

FIG. 14 shows a schematic cross-sectional diagram of a semiconductor structure in accordance with a second embodiment of the invention. Similarly with the first embodiment, the semiconductor structure comprises a field effect transistor structure including a pair of raised source/drain regions 29a″ and 29b″. The pair of raised source/drain regions 29a″ and 29b″ comprises: (1) a pair of intrinsic source/drain regions 28a″ and 28b″ within a surface semiconductor layer 10b of a semiconductor-on-insulator substrate; (2) a pair of implanted patterned epitaxial etch stop semiconductor layers 12a″ and 12b″ located thereupon; and (3) a pair of silicide layers 32a and 32b further located thereupon. The semiconductor structure also illustrates a pair of truncated halo regions 26a″ and 26b″ located within the surface semiconductor layer 10b. Due to the presence of the pair of raised source/drain regions 29a″ and 29b″, the pair of silicide layers 32a and 32b therein may be formed absent intrusion into the pair of intrinsic source/drain regions 28a″ and 28b″.

The preferred embodiments of the invention are illustrative of the invention rather than limiting of the invention. Revisions and modifications may be made to methods, materials, structures and dimensions in accordance with the preferred embodiments of the invention while still providing an embodiment in accordance with the invention, further in accordance with the accompanying claims.

What is claimed is:

1. A semiconductor structure comprising:
a gate electrode located over a channel region within a semiconductor substrate, the channel region separating a pair of source/drain regions that is raised with respect to the channel region, wherein each of the source/drain regions has a surface that has a downward taper in the direction of the gate electrode.

2. The semiconductor structure of claim 1 wherein the surface that has the downward taper in the direction of the gate electrode is an end surface of the source/drain region.

3. The semiconductor structure of claim 1 wherein the downward taper in the direction of the gate electrode is a uniform taper.

4. The semiconductor structure of claim 3 wherein the uniform taper has an angle of 54.7 degrees with respect to the semiconductor substrate.

5. The semiconductor structure of claim 1 further comprising a spacer layer located upon the surface that has the downward taper in the direction of the gate electrode.

6. The semiconductor structure of claim 1 wherein each of the source/drain regions comprises:
an intrinsic source/drain region coplanar with the channel region;
an epitaxial etch stop semiconductor layer located upon the intrinsic source/drain region; and
an epitaxial surface semiconductor layer located upon the epitaxial etch stop semiconductor layer, the epitaxial surface semiconductor layer having the downward taper in the direction of the gate electrode.

7. The semiconductor structure of claim 6 wherein the intrinsic source/drain region and the epitaxial surface semiconductor layer comprise the same semiconductor material.

8. The semiconductor structure of claim 1 wherein each of the source/drain regions comprises:
an intrinsic source/drain region coplanar with the channel region;
an epitaxial etch stop semiconductor layer located upon the intrinsic source/drain region; and
a silicide layer located upon the epitaxial etch stop semiconductor layer, the silicide layer having the downward taper in the direction of the gate electrode.

9. The semiconductor structure of claim 1 wherein the semiconductor substrate comprises a bulk semiconductor substrate.

10. The semiconductor structure of claim 1 wherein the semiconductor substrate comprises a semiconductor-on-insulator substrate.

11. A method for fabricating a semiconductor structure comprising:
patterning at least an epitaxial surface semiconductor layer located over a semiconductor substrate, to form at least a pair of patterned epitaxial surface semiconductor layers separated by a trench that exposes the semiconductor substrate;
forming a gate dielectric upon the semiconductor substrate at the bottom of the trench;
forming a gate electrode upon the gate dielectric; and
forming a pair of source/drain regions into at least the semiconductor substrate while using at least the gate electrode as a mask.

12. The method of claim 11 wherein the forming the gate electrode comprises forming the gate electrode separated from each of the patterned epitaxial surface semiconductor layers.

13. The method of claim 12 further comprising forming a spacer layer interposed between the gate electrode and the pair of patterned epitaxial surface semiconductor layers.

14. The method of claim 13 further comprising siliciding the pair of patterned epitaxial surface semiconductor layers to form a pair of silicide layers.

15. The method of claim 11 wherein the forming the pair of source/drain regions includes forming the pair of source/drain regions into the pair of patterned epitaxial surface semiconductor layers.

16. A method for fabricating a semiconductor structure comprising:
crystallographically specifically etching an epitaxial surface semiconductor layer located upon an epitaxial etch stop semiconductor layer further located upon a semiconductor substrate, to form a pair of patterned epitaxial surface semiconductor layers separated by an outward tapered trench that exposes the epitaxial etch stop semiconductor layer;
etching the epitaxial etch stop semiconductor layer exposed within the outward tapered trench to form a pair of patterned epitaxial etch stop semiconductor layers that exposes the semiconductor substrate;
forming a gate dielectric upon the semiconductor substrate at the bottom of the outward tapered trench;
forming a gate electrode upon the gate dielectric; and
forming a pair of source/drain regions into at least the semiconductor substrate while using at least the gate electrode as a mask.

17. The method of claim 16 wherein the forming the gate electrode comprises forming the gate electrode separated from each of the patterned epitaxial surface semiconductor layers.

18. The method of claim 17 further comprising forming a halo implant region into the semiconductor substrate while using the gate electrode as a mask, a tilt angle from an orthogonal used when forming the halo implant region being less than a taper angle from the orthogonal of the outward tapered trench.

19. The method of claim 17 further comprising forming a spacer layer interposed between the gate electrode and the pair of patterned epitaxial surface semiconductor layers.

20. The method of claim 19 wherein the pair of patterned epitaxial etch stop semiconductor layers serve as a pair of silicide stop layers.
